(19) United States
(12) Patent Application Publication
(10) Pub. No.: US 2021/0297073 A1
(43) Pub. Date: Sep. 23, 2021

(54) Switching Device for Separating a Current Path

(71) Applicant: Siemens Aktiengesellschaft, München (DE)

(72) Inventor: Jürgen Rupp, München (DE)

(73) Assignee: Siemens Aktiengesellschaft, München (DE)

(21) Appl. No.: 17/276,676

(22) PCT Filed: Sep. 17, 2019
(86) PCT No.: PCT/EP2019/074758

§ 371 Date: Mar. 16, 2021

(30) Foreign Application Priority Data
Sep. 18, 2018 (DE) 10 2018 215 827.4

(51) Int. Cl. H03K 17/10

(52) U.S. Cl. CPC H03K 17/107

(57) ABSTRACT

Various embodiments include a switching device for disconnecting a current path in a DC supply system, said current path comprising source-end and load-end inductances, comprising: two series-connected switching modules, wherein each of the switching modules comprises a controllable semiconductor switching element connected in parallel to a series circuit with a resistor and a capacitor. Each resistor includes two respective series-connected resistors. A first end of the respective resistor is connected to a first load terminal of the controllable semiconductor switching element and a second end of the respective resistor is connected to the capacitor. Each of the switching modules comprises a further controllable semiconductor switching element connected between a first node of the two resistors in the respective resistor and a second node connects the capacitor to a second load terminal of the controllable semiconductor switching element.

### CROSS-REFERENCE TO RELATED APPLICATIONS

This application is a U.S. National Stage Application of International Application No. PCT/EP2019/074758 filed Sep. 17, 2019, which designates the United States of America, and claims priority to DE Application No. 10 2018 215 827.4 filed Sep. 18, 2018, the contents of which are hereby incorporated by reference in their entirety.

### TECHNICAL FIELD

The present disclosure relates to DC supply systems. Various embodiments may include switching devices for disconnecting a current path in a DC supply system, wherein the current path comprised source-end and load-end inductances.

### BACKGROUND

A switching device for disconnecting a current path in a DC supply system, said current path comprising source-end and load-end inductances, must be capable of accommodating the recovery or removal of energy from the DC supply system. If mechanical switches or hybrid switches with a mechanical and electronic switching element are employed, there is a resulting risk of the generation of an arc, as it cannot be ensured that the disconnection of the current path will coincide with a zero-crossing of the current. A mechanical switching element of this type must therefore be protected by a complex circuit, e.g. by the provision of a plurality of semiconductor switching elements and varistors as voltage surge limiters.

To this end, in some cases, the high-speed mechanical switch arranged in the main current branch can be interconnected with a semiconductor switching element which, in the conducting state, undergoes a low voltage drop. The function of this semiconductor switching element, upon the disconnection of the load path, is to generate a voltage drop upon disconnection, such that the current can be routed to a main switch which is connected in parallel with this arrangement. This main switch is comprised of a series circuit of a plurality of semiconductor switching elements, for the voltage surge protection of which a varistor is parallel-connected in each case. If the current now flows essentially via the parallel path, the high-speed mechanical switch can be disconnected without generating an arc. A disadvantage of this switching device is the complexity thereof, associated with the plurality of semiconductor switching elements and varistors required, wherein the latter are extremely expensive and cumbersome.

Switching devices may be exclusively comprised of controllable semiconductor switching elements, e.g. IGBTs. In variants of this type, for example, two semiconductor switching elements can be connected in the load path in an anti-series arrangement for bidirectional operation. In the absence of further measures, however, this switching device can only be employed in DC supply systems which do not feature any large inductances. Moreover, voltage-limiting components such as e.g. varistors and the like are required, the use of which, however, is not favored, on the grounds of cost.

PCT/EP2018/054775 describes a switching device addressing the problems mentioned above. The switching device comprises at least two series-connected switching modules. Each of the switching modules comprises at least one controllable semiconductor switching element in the form of an IGBT (Insulated Gate Bipolar Transistor), to which a series circuit consisting of a resistor and a capacitor is connected in parallel. A switching device of this type permits a “soft” switch-off process, wherein the current flow in the current path is not reduced abruptly, but with a ramped characteristic. By means of at least one of the at least two switching modules, a counter-voltage is constituted in the current path. This is made possible by operation of the respective semiconductor switching element of the switching modules in the switched-mode domain.

Accordingly, the high power loss in the event of a switch-off is not implemented in the semiconductor switching element of the respective switching modules, but primarily in the resistor of the respective switching modules. Voltage-limiting components, such as varistors, which are expensive, heavy and cumbersome, can thus be omitted from the switching device. The semiconductor switching element in the respective switching modules thus assumes the function of a brake chopper.

A disadvantage of this switching device, however, is that not only the load current, but also the discharge current of the capacitor, is conducted via the controllable semiconductor switching element. Although the discharge current is conducted only briefly during the switch-off operation, IGBTs are capable of carrying an overcurrent only to a slight extent. Therefore, they must be designed for the worst case, that is to say the maximum possible sum current comprising the load current and the discharge current, which makes it necessary to use components of large dimensions. As a result, the switching device may become undesirably expensive.

### SUMMARY

The teachings of the present disclosure may include switching devices for disconnecting a current path in a DC supply system, said current path comprising source-end and load-end inductances, which switching device is structurally and/or functionally improved further and does not require any overdimensioning of components. In particular, the switching device is intended to be able to be provided at lower cost.

For example, some embodiments include a switching device (1) for disconnecting a current path (6) in a DC supply system, said current path (6) comprising source-end and load-end inductances (3, 5), said switching device comprising at least two series-connected switching modules (10), wherein each of the switching modules (10) comprises at least one controllable semiconductor switching element (13), to which a series circuit consisting of a resistor (14) and a capacitor (15) is connected in parallel, characterized in that the resistor (14) is formed from a series circuit of two series-connected resistors (141, 142), wherein a first end of the series circuit is connected to a first load terminal of the controllable semiconductor switching element (13) and a second end of the series circuit is connected to the capacitor (15), and each of the switching modules (10) also comprises a further controllable semiconductor switching element (16) which is connected between a first node (143) of the two resistors in series circuit and a second node (144) which connects the capacitor (15) to a second load terminal of the controllable semiconductor switching element (13).

In some embodiments, the further controllable semiconductor switching element (16) can be switched to a conducting state and a blocking state via a control signal.

In some embodiments, the further controllable semiconductor switching element (16) is an insulated-gate bipolar transistor (IGBT).

In some embodiments, the further controllable semiconductor switching element (16) is a thyristor.

In some embodiments, the thyristor is of the disconnectable type (GTO, IGCT).

In some embodiments, the thyristor can be turned off by means of a turn-off circuit.

In some embodiments, the controllable semiconductor switching element (13) is an element of the turn-off circuit.

In some embodiments, the turn-off circuit comprises a further capacitor (17) which is connected between the first node and the first load terminal of the controllable semiconductor switching element (13).

In some embodiments, a desired discharge time of the capacitor (15) is set by means of the ratio of the resistance values of the resistors (141, 142) in the series circuit.

### BRIEF DESCRIPTION OF THE DRAWINGS

The teachings herein are explained in greater detail hereinafter, with reference to exemplary embodiments represented in the drawings, in which:

FIG. 1 shows an equivalent electric circuit diagram showing the layout of an individual unidirectional switching module for a known switching device;

FIG. 2 shows an equivalent electric circuit diagram of a serial connection of three switching modules shown in FIG. 1;

FIG. 3 shows an equivalent electric circuit diagram of a switching device incorporating teachings of the present disclosure in a DC supply system having source-end and load-end inductances;

FIG. 4 shows a first exemplary embodiment of an improved switching module incorporating teachings of the present disclosure;

FIG. 5 shows a second exemplary embodiment of an improved switching module incorporating teachings of the present disclosure; and

FIG. 6 shows a diagram showing the characteristic of voltage and current through a further controllable semiconductor switching element; and

FIG. 7 shows a third exemplary embodiment of a switching module incorporating teachings of the present disclosure which allows bidirectional operation.

In the following descriptions, identical elements are provided with the same reference symbols throughout the various figures.

### DETAILED DESCRIPTION

Some embodiments of the teachings herein include a switching device for disconnecting a current path in a DC supply system, said current path comprising source-end and load-end inductances, which switching device comprises at least two series-connected switching modules. Each of the switching modules comprises at least one controllable semiconductor switching element, to which a series circuit consisting of a resistor and a capacitor is connected in parallel.

The teachings herein further develop the switching device known from PCT/EP2018/054775 by virtue of the resistor being formed from a series circuit comprising two series-connected resistors. A first end of the series circuit is connected to a first load terminal of the controllable semiconductor switching element. A second end of the series circuit is connected to the capacitor. Each of the switching modules also comprises a further controllable semiconductor switching element. The further controllable semiconductor switching element is connected between a first node of the two resistors in the series circuit and a second node which connects the capacitor to a second load terminal of the controllable semiconductor switching element.

In the switching devices described herein, the load current flows via the controllable semiconductor switching element, as in the known switching device. In contrast, the discharge current for discharging the capacitor of the switching module is accepted by the further controllable semiconductor switching element. As a result, the controllable semiconductor switching element, which conducts the load current, can be dimensioned for the level of the load current. There is no need for any overdimensioning, as in known switching devices. The switching device provided thereby has lower costs despite the additional components.

In some embodiments, use is made, as a further controllable semiconductor switching element, of a controllable semiconductor switching element which can be switched to a conducting and blocking state via a control signal. For example, the further controllable semiconductor switching element may be an insulated gate bipolar transistor (IGBT). If the further controllable semiconductor switching element is in the form of an IGBT, this results in more degrees of freedom during control. In addition to the function of carrying the discharge current of the capacitor of the switching module, it is also possible to achieve a permanent current flow via the further controllable semiconductor switching element. The resistor in the series circuit of resistors, which is connected upstream of the further controllable semiconductor switching element, can then be used, for example, to attenuate network oscillations or as a load resistor for capacitive loads.

In some embodiments, the further controllable semiconductor switching element is a thyristor. The use of a thyristor as a further controllable semiconductor switching element has the advantage that it can be briefly highly overloaded, with the result that a relatively small type can be used. As a result, the switching device can be implemented at low cost.

In some embodiments, the thyristor is of the disconnectable type, for example a GTO (Gate Turn-Off) thyristor or an IGCT (Integrated Gate-Commutated Thyristor). The use of a thyristor of the disconnectable type makes it possible to end the current flow through the current path of the further controllable semiconductor switching element in a targeted manner.

If it is not intended to use a thyristor of the disconnectable type, in particular on account of high costs and/or poor availability, the thyristor can alternatively be turned off by means of a turn-off circuit. In this case, in particular, the controllable semiconductor switching element which carries the load current of the switching device is an element of the turn-off circuit. As a result, the number of additional elements can be kept low.

In some embodiments, the turn-off circuit comprises a further capacitor which is connected between the first node and the first load terminal of the controllable semiconductor switching element. A further capacitor, which generates a brief negative voltage surge across the thyristor when the controllable semiconductor switching element is switched on, is therefore connected in parallel with that resistor in the series circuit of resistors which is connected in series with the further controllable semiconductor switching element, with the result that the current in the thyristor becomes zero. This makes it possible to turn off the thyristor with little effort.

In some embodiments, a desired discharge time of the capacitor is set by means of the ratio of the resistance values of the resistors in the series circuit. When charging the capacitor, the resistance value which results from the sum of the resistance values of the two resistors in series circuit of resistors is effective. In contrast, when discharging the capacitor, only the resistance value of that resistor which is included in the parallel branch to the further controllable semiconductor switching element is effective.

In some embodiments, the further capacitor has a capacitance value which is less than the capacitance value of the capacitor of the switching module.

The switching device described herein may be used in a DC supply system having a voltage of greater than 1000 V. Depending upon the prevailing voltage in the DC supply system, an appropriate corresponding number of switching modules for the switching device must then be selected. The higher the voltage to be controlled in the DC supply system, the greater the number of switching modules selected will be—subject to the provision of identical semiconductor switching elements. For DC supply systems in the medium-voltage range, IGBTs or MOSFETs can specifically be employed as controllable semiconductor switching elements for switching the load current. At even higher voltages, thyristors having a cut-off device or IGCTs are specifically employed. In some embodiments, it is provided that the switching device of the type described here is employed as a short-circuit-proof power switch.

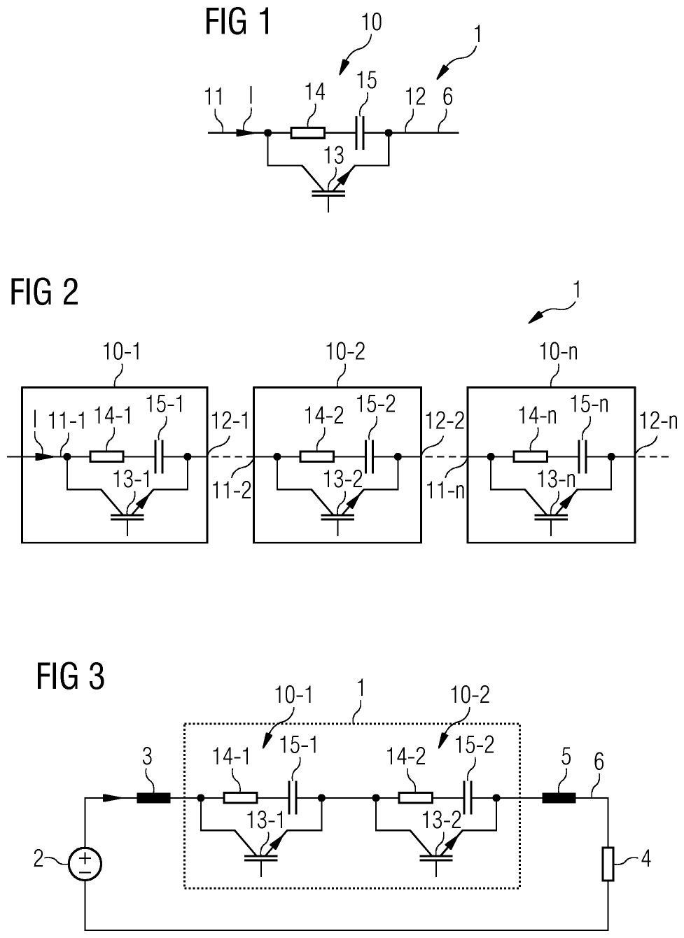

FIG. 1 shows the schematic layout of a switching module 10 of a switching device 1 known from PCT/EP2018/054775 for disconnecting a current path 6 comprising source-end and load-end inductances. The switching module 10 comprises a controllable semiconductor switching element 13. The controllable semiconductor switching element 13 can be an IGBT, a MOSFET, an IGCT or a thyristor having a cut-off device. The load terminals of the controllable semiconductor switching element 13 are connected between a first switching module terminal 11 and a second switching module terminal 12. A series circuit consisting of a resistor 14 and a capacitor is further arranged between the first and second switching module terminals 11, 12. In other words, an RC element constituted by the resistor 14 and the capacitor 15 is connected in parallel with the load terminals of the controllable switching element 13. The diode in anti-series with the IGBT is not illustrated for reasons of clarity. The module can be upgraded for bidirectional operation if the switching element 13 is constructed from two IGBTs connected in anti-series.

The basic mode of operation of such an individual switching module of the switching device 1 is as follows: if the switching device 1 is to conduct current, the controllable semiconductor switching element 13 is switched to a conducting state. Immediately after the current path 6 is to be disconnected by means of the switching device 1, the controllable semiconductor switching element 13 is switched to a blocking state by means of a control device which is not shown in the figures. As a result, the current I flowing in the current path 6 can only continue to flow via the RC element constituted by the resistor 14 and the capacitor 15. The capacitor 15 is charged by the current I flowing into it, until a predefined upper threshold value for the voltage dropped across it is achieved. To this end, a corresponding measuring device (not represented) can be provided in the switching module 10. Immediately after the predefined upper threshold value is achieved, the controllable semiconductor switching element 13 is switched back to a conducting state. The capacitor 15 can thus be discharged via the resistor 14 and the controllable semiconductor switching element 13. Immediately after a predefined lower threshold value for the voltage dropped across the capacitor 15 is achieved, the controllable semiconductor switching element 13 is switched back to a conducting state by means of its control device. The controllable semiconductor switching element 13 therefore need not only be designed for the (load) current I to be conducted, but also for the discharge current resulting from the discharge of the capacitor 13.

If the disconnection of the current path 6 occurs in response to a short circuit in the DC supply system, reclosing (switching of the controllable semiconductor switching element 13 to a conducting state) permits the restoration of the flow of short-circuit current through the switching module 10. However, as the switch-on time of the controllable semiconductor switching element 13 is very short, the current I flowing in the current path 6 is cleared on average as the source-end and load-end inductances 3 and 5 (cf. FIG. 3), which are not shown in FIG. 1, prevent an excessively rapid rise in the current.

Were the switching device 1 to comprise only a single switching module 10, as represented in FIG. 1, voltage control would be restricted to voltages which are lower than the maximum voltage of the controllable semiconductor switching element 13. In the event of higher voltages, associated with a high-speed disconnection process and the occurrence of an overvoltage associated with the presence of inductances in the current path, the controllable semiconductor switching element 13 might be destroyed. Although, in principle, it is possible to provide a single switching module 10 in the switching device 1, this is only appropriate if the DC supply system incorporates high impedances.

In order to permit the disconnection of a current path in a DC supply system having higher voltages by means of the switching device 1 proposed, according to FIG. 2, the series connection of a plurality of switching modules as shown in FIG. 1 is therefore provided.

FIG. 2 shows an equivalent electric circuit diagram of a serial connection of n switching modules 10-1, 10-2, . . . , 10-n (in general: 10-i, where i=1 to n). Each of the switching modules 10-i is constituted in the manner described in FIG. 1. Serial connection of the switching modules 10-i is executed such that the second switching module terminal 12-1 of the first switching module 10-1 is connected to the first switching module terminal 11-2 of the next switching module 10-2 in sequence, and so forth. The first switching module terminal 11-1 of the first switching module 10-1, as shown in FIG. 3, is connected to a DC voltage source 2 via a source-end inductance 3. The DC voltage source 2, for example, can be an energy generating unit, e.g. a photovoltaic installation, a storage system, a battery charging device, a wind energy installation, a rectifier and the like. The second switching module terminal 12-n of the final switching module 10-n, as shown in FIG. 3, is connected to a load 4 via a load-end inductance 6. The load 4 can be, for example, a drive system on a DC supply system, or similar.

FIG. 3 shows the equivalent electric circuit diagram of a switching device 1, which is comprised of two series-connected switching modules 10-1 and 10-2, each of which is constituted as described in FIG. 1. The switching device 1 is connected to the DC voltage source 2 via the above-mentioned source-end inductance 3. On the output side, the switching device 1 is connected to the load 4 via the load-end inductance 5. The source-end and load-end inductances 3, 5 do not necessarily need to constitute physical components of the DC supply system. The source-end and load-end inductances 3, 5 can also be line inductances.

The mode of operation of the switching device shown in FIG. 3 is as follows: if the load 4 is to be supplied with current from the DC voltage source 2, the controllable semiconductor switching elements 13-1, 13-2 (in general: 13-i, where i=1 to 2) of the switching modules 10-1, 10-2 (in general: 10-i, where i=1 to 2) are switched to a conducting state. Immediately after the current path 6 is to be disconnected, e.g. on the grounds of a load-end short circuit, both controllable semiconductor switching elements 13-i are firstly switched to a blocking state, such that the current I can only flow via the two RC elements of the switching modules 10-i. The capacitors 15-1, 15-2 (in general: 15-i, where i=1 to 2) are charged, until a respective predefined upper threshold value is achieved. The same or a different predefined upper threshold value can be selected for both capacitors 15-i. Initially, one of the controllable semiconductor switching elements 13-1 or 13-2 of the switching module 10-1 or 10-2 is switched back to a conducting state, such that the associated capacitor 15-1 or 15-2 is discharged via the series-connected resistor 14-1 or 14-2. Immediately after a predefined lower threshold value is achieved, the corresponding controllable semiconductor switching element is switched back to a blocking state. Simultaneously, or with a short temporal offset thereafter, the other controllable semiconductor switching element 13-2 or 13-1 is switched to a conducting state, if its predefined upper threshold value has been achieved. Accordingly, the two controllable semiconductor switching elements 13-1, 13-2 are switched to a conducting state in an alternating manner, thus ensuring that a total voltage U_{ges} is present across both controllable semiconductor switching elements 13-i in combination, by means of which the current flow, and thus the energy stored in the inductances 3, 5, is cleared.

Unlike in the case of the use of a single switching module, in the case of a plurality of switching modules, a counter-voltage (i.e. a voltage which is oriented in opposition to the voltage direction of the DC voltage source 2) is consistently present in the DC supply system. If the number n of series-connected switching modules is very large, the short-term short-circuiting of one switching module is scarcely of any significance, as a result of which the current is cleared gradually.

Immediately after the predefined upper switching threshold in all the controllable semiconductor switching elements 13-i is no longer achieved, all the controllable semiconductor switching elements 13-i of the switching modules 10-i will remain permanently blocked. The voltage in the DC supply system will then oscillate with a natural resonance.

The methods described, independently of the magnitude of the number n of series-connected switching modules, are executed in a corresponding manner. Which of the controllable semiconductor switching elements 13-i, at any given time point, are in a blocking state, and which other controllable semiconductor switching elements 13-i are switched to a conducting state, can be effected by means of deliberate control of the above-mentioned, but unrepresented control unit. Likewise, by means of the appropriate and differing selection of respective upper switching thresholds, the temporal characteristic of the switch-on and switch-off of the associated controllable semiconductor switching element can be influenced.

In some embodiments, the voltage present across the respective capacitors 15-i can be monitored by corresponding measuring means (not shown). The controllable semiconductor switching element assigned to the capacitor on which the highest voltage is present is switched, in this case, to a conducting state, until the predefined lower threshold value is achieved. Given that, consistently, at different time points, different switching modules or the capacitors thereof have the highest voltage, the switch-on and switch-off of the controllable semiconductor switching elements 13-i of the switching modules 10-i occurs in a more or less randomized manner.

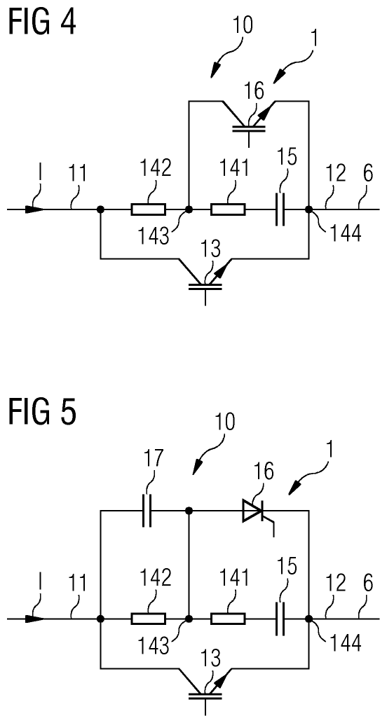

FIGS. 4 and 5 show the equivalent electric circuit diagrams of two exemplary embodiments of an improved switching device 1, in which the controllable semiconductor switching element 13 can be dimensioned independently of the discharge current resulting from the discharge of the capacitor 15. In other words, in the improved switching devices 1 incorporating teachings of the present disclosure, the controllable semiconductor switching element 13 is primarily responsible for conducting the load current I and can be dimensioned for this. The discharge current resulting from the discharge of the capacitor 15 is accepted via a further controllable semiconductor switching element 16. This may be an IGBT, as shown in the exemplary embodiment according to FIG. 4, or a thyristor, as shown in the exemplary embodiment according to FIG. 5.

In a modification of the switching device 1 known from FIG. 1, the resistor 14 is formed from a series circuit of two series-connected resistors 141, 142. A first end of the series circuit is connected to a first load terminal of the controllable semiconductor switching element 13 and therefore to the first switching module terminal 11. A second end of the series circuit is connected to the capacitor 15. The IGBT according to FIG. 4 is connected between a first node 143 of the resistors 141, 142 in the series circuit and a second node 144 which constitutes the second switching module terminal 12. The second node 144 or the second switching module terminal 12 connects the capacitor 15 to the second load terminal of the controllable semiconductor switching element 13.

The IGBT 16 and the controllable switching element 13 can be switched at approximately the same time. The capacitor 15 is then discharged via the resistor 141 and the IGBT 16. In contrast, when the semiconductor switching elements 13, 16 are switched to a blocking state, the capacitor is charged via both resistors 141, 142. The discharge time of the capacitor 15 can be set by selecting the resistance value 141.

According to the solution shown in FIG. 4, degrees of freedom result during control since the IGBT can be controlled precisely without further components. In addition to the pure discharge function for the capacitor 15, a permanent current flow through the resistor 142 and the IGBT 16 can also be achieved. The resistor 142 can therefore be used, for example, to attenuate network oscillations or as a charging resistor for capacitive loads.

In the implementation variant illustrated in FIG. 5, a thyristor 16, which can be provided at lower cost than an IGBT, is illustrated as a further controllable semiconductor switching element. In addition, thyristors have the advantage over IGBTs that they can be briefly highly overloaded, with the result that the thyristor can have small dimensions.

A known disadvantage of thyristors is that a direct current is not extinguished by itself, with the result that the load current I would continue to flow even after the capacitor 15 has been discharged and when the controllable semiconductor switching element 13 is in a blocked state. In order to solve this problem, a thyristor of the disconnectable type, for example a GTO or an IGCT, can be used as the thyristor 13. However, they have the disadvantage of high costs and poor availability. Alternatively, a so-called turn-off circuit can also be arranged above the thyristor 16. The variant shown in FIG. 5 uses the elements of the switching device which are already available and provides such a turn-off circuit in interaction with a further capacitor 17. The turn-off circuit is used to generate a short circuit of the thyristor. The further capacitor 17 is connected in parallel with the resistor 142. This means that the capacitor 17 is connected between the first switching module terminal 11 and the first node 143. The capacitance value of the further capacitor 17 is less than the capacitance value of the capacitor 15. With the aid of the further capacitor 17, which generates a brief negative voltage surge across the thyristor 16 when the controllable semiconductor switching element 13 is switched on, the current becomes zero, as a result of which the current flow through the thyristor can be stopped.

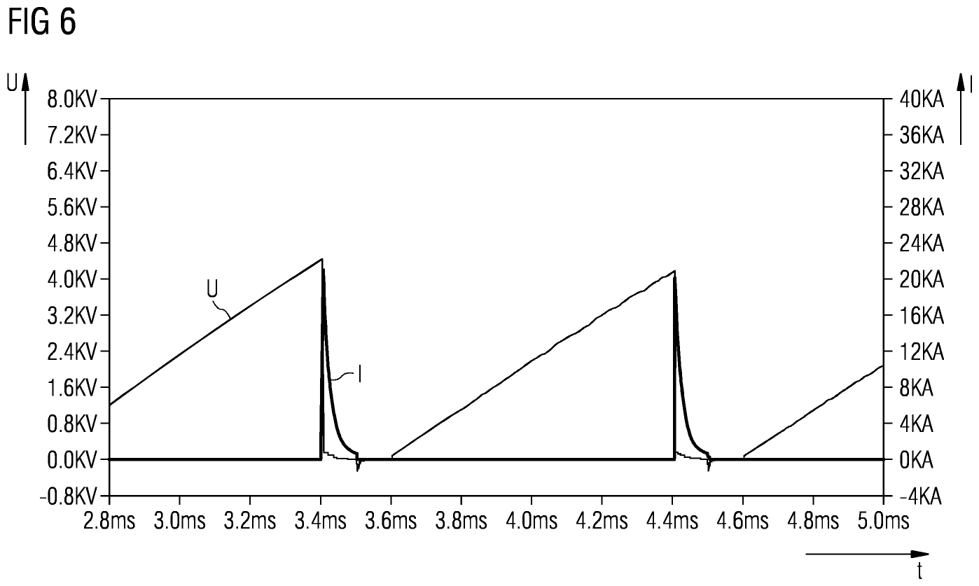

FIG. 6 shows a diagram showing the characteristic of the voltage and current through the further controllable semiconductor switching element. It can clearly be seen that the current flow via the further controllable semiconductor switching element rises briefly during the discharge of the capacitor 15, and the voltage simultaneously falls from a maximum value to zero. After the capacitor has been discharged, the capacitor 15 is gradually charged again until it is discharged again by the further controllable semiconductor switching element.

The two variants described can be used in the arrangements according to FIGS. 2 and 3 instead of in the switching device shown in FIG. 1.

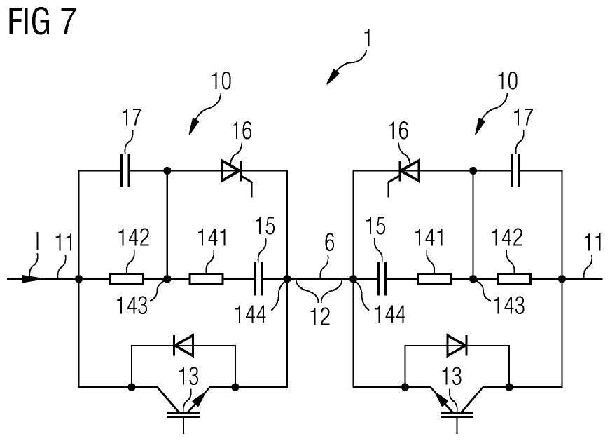

A switch for bidirectional operation can be achieved by connecting two modules in anti-series, as shown and described in FIG. 4. This is illustrated in FIG. 7.

### LIST OF REFERENCE SYMBOLS

1 Switching device
2 DC voltage source
3 Source-end inductance
4 Load
5 Load-end inductance
6 Line to be disconnected
10 Switching module
10-1, . . . , 10-n Switching module
11 First switching module terminal
11-1, . . . , 11-n First switching module terminal
12 Second switching module terminal
12-1, . . . , 12-n First switching module terminal
13 Semiconductor switching element
13-1, . . . , 13-n Semiconductor switching element
14 Resistor
14-1, . . . , 14-n Resistor
15 Capacitor
15-1, . . . , 15-n Capacitor
16 Further controllable semiconductor switching element
17 Further capacitor
141 Resistor
142 Resistor
143 First node
144 Second node
U Voltage
I Current
t Time

What is claimed is:

1. A switching device for disconnecting a current path in a DC supply system, said current path comprising source-end and load-end inductances, the switching device comprising:
two series-connected switching modules, wherein each of the switching modules comprises a controllable semiconductor switching element connected in parallel to a series circuit with a resistor and a capacitor;
wherein each resistor includes two respective series-connected resistors;
wherein a first end of the respective resistor is connected to a first load terminal of the controllable semiconductor switching element and a second end of the respective resistor is connected to the capacitor; and
each of the switching modules comprises a further controllable semiconductor switching element connected between a first node of the two resistors in the respective resistor and a second node connects the capacitor to a second load terminal of the controllable semiconductor switching element.

2. The switching device as claimed in claim 1, wherein the further controllable semiconductor switching element can be switched to a conducting state and a blocking state via a control signal.

3. The switching device as claimed in claim 1, wherein the further controllable semiconductor switching element is an insulated-gate bipolar transistor.

4. The switching device as claimed in claim 1, wherein the further controllable semiconductor switching element comprises a thyristor.

5. The switching device as claimed in claim 4, wherein the thyristor is disconnectable.

6. The switching device as claimed in claim 4, wherein the thyristor can be turned off by a turn-off circuit.

7. The switching device as claimed in claim 6, wherein the controllable semiconductor switching element is an element of the turn-off circuit.

8. The switching device as claimed in claim 6, wherein the turn-off circuit comprises a further capacitor connected between the first node and the first load terminal of the controllable semiconductor switching element.

9. The switching device as claimed in claim 1, wherein a desired discharge time of the capacitor is set by the ratio of the resistance values of the resistors in the series circuit.
